(19) United States
(12) Patent Application Publication
(10) Pub. No.: US 2005/0151177 A1
(43) Pub. Date: Jul. 14, 2005

(54) Ferroelectric film, ferroelectric capacitor, and ferroelectric memory

(76) Inventors: Hiromu Miyazawa, Nagano-ken (JP); Takeshi Kijima, Nagano-ken (JP); Eiji Natori, Chino-shi (JP); Taku Aoyama, Tokyo (JP)

Correspondence Address: HARNESS, DICKEY & PIERCE, P.L.C., P.O. BOX 828, BLOOMFIELD HILLS, MI, 48303, US

(21) Appl. No.: 10/980,748

(22) Filed: Nov. 3, 2004

(30) Foreign Application Priority Data
Nov. 5, 2003 (JP) 2003-375501
Sep. 30, 2004 (JP) 2004-287087

(51) Int. Cl. H01L 29/76

(52) U.S. Cl. 257/295

(57) ABSTRACT

A ferroelectric film is provided that is expressed by a general formula of A_{1-b}B₁₋ₐXₐO₃, wherein: A includes Pb; B is composed of at least one of Zr and Ti; X is composed of at least one of V, Nb, Ta, Cr, Mo and W; a is in a range of 0.05≦a≦0.3; and b is in a range of 0.025≦b≦0.15.

### RELATED APPLICATIONS

This application claims priority to Japanese Patent Application Nos. 2003-375501 filed Nov. 5, 2003, and 2004-287087 filed Sep. 30, 2004 which are hereby expressly incorporated by reference herein in their entirety.

### BACKGROUND

1. Technical Field

The present invention relates to ferroelectric films, ferroelectric capacitors, and ferroelectric memories.

2. Technical Background

In recent years, research and development of ferroelectric films such as Pb(Zr, Ti)O₃(PZT), SrBi₂Ta₂O₉ (SBT), ferroelectric capacitors, ferroelectric memory devices and the like using these films have been extensively conducted. The structure of ferroelectric memory devices is roughly divided into a 1T, a 1T1C, a 2T2C, and a simple matrix type. Among them, the 1T type has a retention (data retention) that is as short as one month since an internal electric field occurs in the capacitor due to its structure, and it is said to be impossible to ensure a 10-year guarantee generally required for semiconductors. Because the 1T1C type and 2T2C type have substantially the same structure as that of a DRAM, and include selection transistors, such that they can take advantage of the DRAM manufacturing technology, and realize write speeds comparable to those of SRAMs, they have been manufactured so far into commercial products with a small capacity of 256-kbit or less.

PZT has been mainly used so far as a ferroelectric material used for ferroelectric memory devices of 1T1C type or 2T2C type. In the case of these material, compositions in a region where rhombohedral and tetragonal coexist with the Zr/Ti ratio being 52/48 or 40/60 or compositions in the neighborhood thereof are used, and also these material are used with an element such as La, Sr, Ca or the like being doped. This region is used because the reliability that is most essential for memory devices is to be secured.

In other words, although the hysteresis shape is good in a Ti rich tetragonal region, but Schottky defects that originate in ionic crystal structure occur in the tetragonal region. As a result, defects in leakage current characteristics or imprint characteristics (so-called degree of deformation of hysteresis) are generated, and thus it is difficult to secure the reliability. For this reason, the above-described compositions in the region where rhombohedral and tetragonal coexist, or compositions near that region are used.

On the other hand, a simple matrix type has a smaller cell size compared to the 1T1C type and 2T2C type and allows multilayering of capacitors, such that a higher integration and a cost reduction are expected. Conventional simple matrix type ferroelectric memory devices are described in Japanese Laid-open Patent Application HEI 9-116107 and the like. This Laid-open Patent Application describes a drive method in which a voltage that is one-third a write voltage is applied to non-selected memory cells when writing data into the memory cells.

A hysteresis loop having good squareness is indispensable to obtain a simple matrix type ferroelectric memory device. As a ferroelectric material that can handle such a requirement, Ti rich tetragonal PZT can be considered as a candidate, but it is difficult to secure its reliability like the aforementioned 1T1C type and 2T2C type ferroelectric memory devices.

It is an object of the present invention to provide a 1T1C, 2T2C, and simple matrix type ferroelectric memory, which includes a ferroelectric capacitor having hysteresis loop characteristics usable to any of the 1T1C, 2T2C, and simple matrix type ferroelectric memory. Also, another object of the present invention is to provide a ferroelectric film that is suitable for the ferroelectric memory.

### SUMMARY

A ferroelectric film in accordance with the present invention is expressed by a general formula of A_{1-b}B₁₋ₐXₐO₃, wherein: A is composed of at least Pb; B is composed of at least one of Zr and Ti; X is composed of at least one of V, Nb, Ta, Cr, Mo and W; a is in a range of 0.05≦a≦1; and b is in a range of 0.025≦b≦0.15.

According to this ferroelectric film, by substituting the X whose valence is higher than that of the B for the B in the B site having a perovskite type structure, the neutrality of the crystal structure as a whole can be retained. As a result, oxygen vacancy can be prevented. Accordingly, current leakages of the ferroelectric film can be prevented. Also, imprint, retention, fatigue characteristics of the ferroelectric film can be made excellent.

In the ferroelectric film in accordance with the present invention, typically, A is composed of Pb, and B is composed of Zr and Ti. In this case, the above-described general formula, A_{1-b}B₁₋ₐXₐO₃, becomes Pb_{1-b}(Zr, Ti)₁₋ₐXₐO₃. It is noted that the same applies to A and B to be described below.

A ferroelectric film in accordance with the present invention is expressed by a general formula of A_{1-b-c}B₁₋ₐXₐO_{3-c}, wherein: A is composed of at least Pb; B is composed of at least one of Zr and Ti; X is composed of at least one of V, Nb, Ta, Cr, Mo and W; a is in a range of 0.05≦a≦0.3; b is in a range of 0.025≦b≦0.15; and c is in a range of 0≦d≦0.03.

According to this ferroelectric film, by substituting the X whose valence is higher than that of the B for the B in the B site having a perovskite type structure, the neutrality of the crystal structure as a whole can be retained. As a result, oxygen vacancy can be prevented. Accordingly, current leakages of the ferroelectric film can be prevented. Also, imprint, retention, fatigue characteristics of the ferroelectric film can be made excellent.

A ferroelectric film in accordance with the present invention is expressed by a general formula of (A_{1-d}Z_{d})_{1-b-c}B₁₋ₐXₐO_{3-C}, wherein: A is composed of at least Pb; Z is composed of at least one of elements having a valence higher than A; B is composed of at least one of Zr and Ti; X is composed of at least one of V, Nb, Ta, Cr, Mo and W; a is in a range of 0.05≦a≦0.3; b is in a range of 0.025≦b≦0.15; c is in a range of 0≦d≦0.03; and d is in a range of 0≦d≦0.05.

According to this ferroelectric film, by substituting the X whose valence is higher than that of the B for the B in the B site having a perovskite type structure, the neutrality of the crystal structure as a whole can be retained. As a result, oxygen vacancy can be prevented. Accordingly, current leakages of the ferroelectric film can be prevented. Also, imprint, retention, fatigue characteristics of the ferroelectric film can be made excellent.

In the ferroelectric film in accordance with the present invention, the Z may be composed of at least one of La, Ce, Pr, Nd and Sm.

In the ferroelectric film in accordance with the present invention, the X may be composed of at least one of V, Bn and Ta, and a vacancy amount b of the A may be about a half of a doping amount a of the X.

In the ferroelectric film in accordance with the present invention, the X may be composed of at least Cr, Mo and W, and a vacancy amount b of the A is about the same as a doping amount a of the X.

In the ferroelectric film in accordance with the present invention, the X may include X1 and X2, a composition ratio of the X1 and the X2 may be expressed by (a−e): e, the X1 may be composed of at least one of V, Nb and Ta, the X2 may be composed of at least one of Cr, Mo and W, and a vacancy amount b of the A may be about the sum of a half of a doping amount of the X1 (a−e)/2 and a doping amount e of the X2.

In the ferroelectric film in accordance with the present invention, the X may exist in the B site having a perovskite type structure.

In the ferroelectric film in accordance with the present invention, a composition ratio of Zr and Ti in the B may be expressed by (1−p):p, where p may be in a range of 0.3≦p≦1.0.

In the ferroelectric film in accordance with the present invention, the ferroelectric film may include Si, or Si and Ge.

The ferroelectric film in accordance with the present invention may have a tetragonal structure, and is preferentially oriented to psuedo-cubic (111).

In the present invention, being “preferentially oriented” means to include a case where 100% of the crystals are in a desired (111) orientation, and a case where most of the crystals (for example, 90% or more) are in a desired (111) orientation, and the remaining crystals are in another orientation (for example, (001) orientation).

Also, in the present invention, being “preferentially oriented to psuedo-cubic (111)” means to be preferentially oriented to (111) in the expression of psuedo-cubic. This similarly applies, without being limited to psuedo-cubic (111), to psuedo-cubic (001), for example.

A ferroelectric capacitor in accordance with the present invention may have the ferroelectric film described above.

A ferroelectric memory in accordance with the present invention may have the ferroelectric film described above.

### BRIEF DESCRIPTION OF THE DRAWINGS

FIG. 1 is a cross-sectional view showing a ferroelectric capacitor in accordance with a first embodiment.

FIG. 2 is an explanatory view of a perovskite type crystal structure.

FIG. 3 is an explanatory view of a perovskite type crystal structure.

FIG. 4 is a view showing a XRD pattern of a ferroelectric film of Experimental Example 1.

FIG. 5 is a view showing hysteresis characteristics of the ferroelectric film of Experimental Example 1.

FIG. 6 is a view showing leakage current characteristics of the ferroelectric film of Experimental Example 1.

FIG. 7 is a view showing fatigue characteristics of the ferroelectric film of Experimental Example 1.

FIG. 8 is a view showing static imprint characteristics of the ferroelectric film of Experimental Example 1.

FIG. 9 is a view showing static imprint characteristics of PZT (Zr/Ti=20/80).

FIG. 10 is a view showing static imprint characteristics of PZT (Zr/Ti=30/70).

FIG. 11 is a view showing a result of secondary ion mass spectrometry of the ferroelectric film of Experimental Example 1.

FIG. 12 is a view showing a result of secondary ion mass spectrometry of the ferroelectric film of Experimental Example 1.

FIG. 13 is a view showing hysteresis characteristics of a ferroelectric film of Experimental Example 2.

FIG. 14 is a view showing hysteresis characteristics of a ferroelectric film of Experimental Example 2.

FIG. 15 is a view showing hysteresis characteristics of a ferroelectric film of Experimental Example 2.

FIG. 16 is a view showing hysteresis characteristics of a ferroelectric film of Experimental Example 2.

FIG. 17 is a view showing hysteresis characteristics of a ferroelectric film of Experimental Example 2.

FIG. 18 is a view showing hysteresis characteristics of a ferroelectric film of Experimental Example 2.

FIG. 19 is a view showing Raman optical spectra of a PTN film.

FIG. 20 is a view showing relation between peak positions originated from B site ion and the doping amount of Nb.

FIG. 21 is a view showing relation between peak positions originated from B site ion and the doping amount of Nb.

FIG. 22 is a view showing Raman optical spectra of PT films in which the doping amount of Si is changed.

FIG. 23 is a view showing Raman optical spectra of PT films in which the doping amount of Si is changed.

FIG. 24 is a view schematically showing a P-V hysteresis curve of a ferroelectric capacitor.

FIG. 25 is a plan view schematically showing a simple matrix type ferroelectric memory device.

FIG. 26 is a cross-sectional view schematically showing a simple matrix type ferroelectric memory device.

FIG. 27 is a cross-sectional view schematically showing a ferroelectric memory device.

FIG. 28 is a cross-sectional view schematically showing a 1T1C type ferroelectric memory.

FIG. 29 is an outline diagram of an equivalent circuit of a 1T1C type ferroelectric memory.

### DETAILED DESCRIPTION

Preferred embodiments of the present invention are described below with reference to the accompanying drawings.

### 1. First Embodiment

1-1.

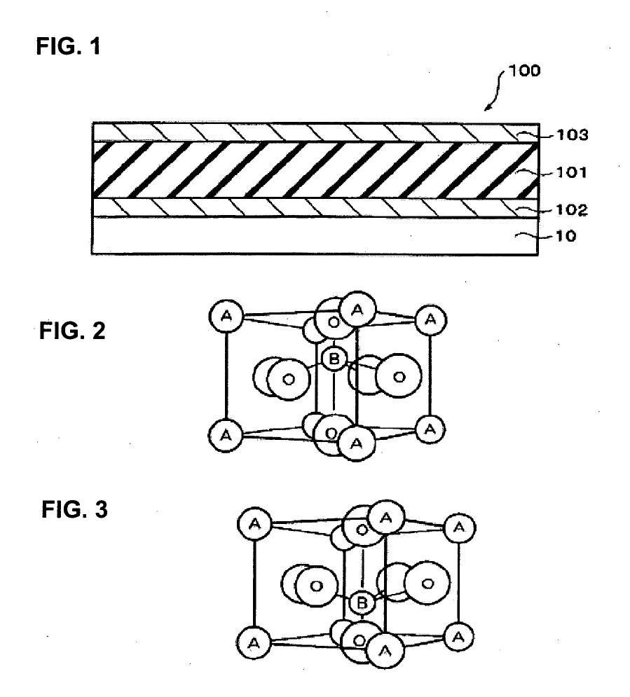

FIG. 1 is a cross-sectional view schematically showing a ferroelectric capacitor 100 using a ferroelectric film 101 in accordance with an embodiment of the present invention.

As shown in FIG. 1, the ferroelectric capacitor 100 is composed of a substrate 10, a first electrode 102, a ferroelectric film 101 formed on the first electrode 102, and a second electrode 103 formed on the ferroelectric film 101.

The thickness of the first electrode 102 and the second electrode 103 is about 50-150 nm, for example, and the thickness of the ferroelectric film 101 is about 50-300 nm, for example.

The ferroelectric film 101 has a perovskite type crystal structure, and can be expressed by a general formula of A_{1-b}B₁₋ₐXₐO₃. A includes Pb. B is composed of at least one of Zr and Ti. X is composed of at least one of V, Nb, Ta, Cr, Mo and W. For example, the ferroelectric film 101 may be composed of Pb_{1-b}(Zr, Ti)₁₋ₐXₐO₃ (hereafter referred to as “PZTX”) having a perovskite type crystal structure. PZTX is Pb (Zr₁₋ₚTiₚ) O₃ (hereafter referred to as “PZT”) having a perovskite type crystal structure with X added thereto. The doping amount of X is indicated by a in the aforementioned formula. The perovskite type has crystal structures indicated in FIG. 2 and FIG. 3, and a position indicated by A in FIG. 2 and FIG. 3 is called an A site, and a position indicated by B is called a B site. In PZTX, Pb is located in the A site, and Zr, Ti and X are located in the B site. Further, O (oxygen) is located at positions indicated by O in FIG. 2 and FIG. 3. In the aforementioned composition formula A_{1-b}B₁₋ₐXₐO₃, b represents the amount of vacancy in the A site.

p in the composition formula Pb(Zr₁₋ₚTiₚ)O₃, which is the base of PZT, may preferably be in a range of 0.3≦p≦1.0, and more preferably in a range of 0.5≦p≦0.8.

a is in a range of 0.05≦a≦0.3, and b is in a range of 0.025≦b≦0.15.

X can be a metal element having a valence higher than that of Zr and Ti. Metal elements having a valence higher than that of Zr or Ti (a valence of +4) include, for example, V (a valence of +5), Nb (a valence of +5), Ta (a valence of +5), Cr (a valence of +6), Mo (a valence of +6), W (a valence of +6), and the like. In other words, X can be at least one kind selected from among V, Nb, Ta, Cr, Mo and W, for example.

Pb system with a perovskite type structure, such as, for example, PZT, has a high vapor pressure, such that Pb located at A the site in the perovskite type structure would likely evaporate during a film forming process. In the above-described PZTX, b in the formula Pb_{1-b}(Zr, Ti)₁₋ₐXₐO₃ indicates the amount of vacancy of Pb. As Pb vacates from the A site, oxygen is vacated at the same time due to the principle of charge neutralization. This phenomenon is called the Schottky vacancy. When oxygen vacancy occurs, the following problems occur concerning the device reliability. For example, when oxygen is vacated in PZT, the band gap of the PZT lowers. Due to the lowered band gap, the band offset at a metal electrode interface reduces, and leakage current characteristics of a ferroelectric film composed of PZT, for example, deteriorate. The band gap lowers because the electrostatic potential of d-orbital electrons of most adjacent transition metal atoms in the B site relatively lowers due to the oxygen vacancy. Also, the presence of oxygen vacancy causes an oxygen ion current, and the ion current causes charge accumulation at an electrode interface, which causes deterioration of imprint, retention, and fatigue characteristics. Diffusion paths of oxygen ions in crystals extend along a defect network in the oxygen octahedron in the perovskite type structure. This can be shown by a molecular dynamics calculation. Accordingly, how to suppress oxygen vacancy becomes a key technology to realize a ferroelectric memory having a high reliability.

In accordance with the present invention, by substituting X having a valence higher than the valence (a valence of +4) of Zr and Ti for elements (Zr, Ti) at the B site, oxygen would not be vacated even when Pb vacancy occurs, and the neutrality of the crystal structure as a whole can be retained. By this, current leakage of the ferroelectric film 101 can be prevented. Also, imprint, retention and fatigue and other characteristics of the ferroelectric film 101 can be made excellent.

For example, when X is composed of Nb, it is hard for atoms to slip out the lattice even by collision among atoms by lattice vibration because Nb has generally the same size as that of Ti (ionic radii are close to each other), and weighs two times. The fact that the ionic radii are close to each other indicates that it is easy for Nb to enter the B site of the perovskite type structure that PZT essentially forms. Moreover, Nb has a very strong covalent bond with oxygen, and is expected to increase ferroelectric characteristics indicated by the Curie temperature and polarization moment, and piezoelectric characteristics indicated by the piezoelectric constant (H. Miyazawa, E. Natori, S. Miyashita; Jpn. J. Appl. Phys. 39 (2000) 5679). It is noted that an example in which X is composed of Nb is described here, but when X includes at least one of V, Ta, Cr, Mo and W, equal or similar effects can be obtained. Nb is the most desirable material in view of the fact that its ionic radius is close to that of Ti, and has a high covalent bond with oxygen.

When X is an element with a valence of +5, the doping amount a of X is preferably in a range of 0.10≦a≦0.30. In this instance, the vacancy amount b of Pb is preferably about a half of the doping amount a of X according to the principle of charge neutralization. In other words, the vacancy amount b of Pb is indicated as b≅a/2, and is preferably be in a range of 0.025≦b≦0.15.

The reason why the vacancy amount b of Pb is preferably about a half of the doping amount a of X is as follows.

First, because the vapor pressure of Pb (a valence of +2) is high, it is likely to vacate from an A site. When Pb (a valence of +2) vacates from the A site, the charge balance is destroyed, oxygen (a valence of −2) is lost according to the principle of charge neutralization, and a Schottky defect is created. In order to suppress generation of a Schottky defect, the charge balance needs to be maintained even when Pb is vacated, and oxygen needs to be prevented from being vacated.

A charge that is lost according to the vacancy amount b of Pb in the composition formula of Pb_{1-b}(Zr, Ti)₁₋ₐXₐO₃ is b×(a valence of −2), and a charge that is gained by the doping amount a of X (a valence of +5) is a×(a valence of +1), as it is replaced with an element having a valence of +4.

In view of the above, if a relation in which the lost charge that is b×(a valence of −2) is generally equal to the gained charge that is a×(a valence of +1), namely, 2b≅a, is established, the charge balance can be maintained without oxygen being lost. Accordingly, the vacancy amount b of Pb is preferably about a half of the doping amount a of X, namely, b≅a/2.

Also, according to the first principle theory electron state calculation, when b≅a/2, the band gap of the system opens. If this relation is not met, in other words, when b<a/2, or when b>a/2, an impurity level is formed immediately below the conduction band, or immediately above the valence band, respectively, and either of the cases indicates that the band gap width lowers. Accordingly, the vacancy amount b of Pb is preferably about a half of the doping amount a of X. It is noted that the range of a and b has actually to do with measurement errors or the like. This similarly applies to all the numerical ranges to be described below.

The numerical ranges described above have the following significance. When the doping amount a of X is less than 0.05, the current leakage prevention effect is not improved by the doping, and when the doping amount a of X exceeds 0.30, the leakage current increases, and a good hysteresis loop cannot be obtained. When X is an element with a valence of +5, that element may be, for example, V, Nb, Ta, or the like, but a preferred element is Nb or Ta, and a more preferred element is Nb.

When X is an element with a valence of +6, the doping amount a of X may preferably be in a range of 0.05≦a≦0.15. In this instance, the vacancy amount b of Pb is preferably about the same as the doping amount a of X, based on the principle of charge neutralization. The absence amount b of Pb is indicated by b≅a, and may preferably be in a range of 0.05≦b≦0.15.

When the doping amount a of X is less than 0.05, the current leakage prevention effect is not improved by the doping, and when the doping amount a of X exceeds 0.30, the leakage current increases, and a good hysteresis loop cannot be obtained. When X is an element with a valence of +6, that element may be, for example, Cr, Mo, W or the like, but a preferred element is Mo or W, which has a large ionic radius, and a high covalent bond with oxygen.

When X includes X1 (a valence of +5) and X2 (a valence of +6), a general formula of the ferroelectric film 101 is expressed by A_{1-b}B₁₋ₐX1ₐ₋ₑX2ₑO₃. (a−e) indicates the doping amount of X1, and e indicates a doping amount of X2. In this case, the doping amount (a−e) of X1 and the doping amount e of X2 may preferably be in a range of 0.05≦(a−e)/2+e≦0.15. In this instance, the vacancy amount b of Pb is preferably about the same as the sum of a half of the doping amount (a−e)/2 of X1 and the doping amount e of X2, based on the principle of charge neutralization. The absence amount b of Pb is indicated by b≅(a−e)/2+e, and may preferably be in a range of 0.05≦b≦0.15.

When the sum of a half of the doping amount (a−e)/2 of X1 and the doping amount e of X2, (a−e)/2+e (hereafter simply referred to as the “sum amount f”), is less than 0.05, the current leakage prevention effect is not improved by the doping, and when the sum amount f exceeds 0.15, the leakage current increases. A preferred element as X1 may be Nb or Ta, and a preferred element as X2 may be Mo or W, which has a large ionic radius. In view of a high covalent bond with oxygen, Nb as X1, and Mo as X2 are most preferable.

It is noted that the aforementioned ferroelectric film 101 is expressed by a general formula of A_{1-b}B₁₋ₐXₐO₃, and O (oxygen) is not vacated. However, a small amount of O can be vacated. Namely, in this case, the general formula is expressed by A_{1-b-c}B₁₋ₐXₐO_{3-c}. In this case, the vacancy amount c of oxygen may preferably be in a range of 0≦c≦0.03.

When the vacancy amount c of oxygen is too large, the band gap lowers, and the bond offset with a metal electrode lowers which causes an increase in leakage current. Accordingly, c is preferably close to zero as much as possible.

Also, Pb at the A site of the perovskite type structure in the ferroelectric film 101 may be partially replaced with Z having a valence that is higher than that of Pb (a valence of +2). In other words, the general formula of the ferroelectric film 101 in this case is expressed by (A_{1-d}Z_{d})_{1-b}B₁₋ₐXₐO₃. The doping amount d of Z may preferably be in a range of 0≦d≦0.05.

Z may be, for example, a lanthanoid element, such as, La, Ce, Pr, Nd, Pm, Sm, Eu, Gd, Tb, Dy, Ho, Er, Tm, Yb, and Lu. Preferred elements are those with a valence of +3, which are La, Pr, Nd or Sm. In this manner, by substituting a part of Pb for an element having a greater valence than that of Pb, the valence caused by the vacated Pb can be supplemented. Moreover, because La, Pr, Nd and Sm have an ionic radius that is close to that of Pb, they can be readily introduced in the A site in the perovskite type structure.

1-2. Methods for Manufacturing a Ferroelectric Film and a Ferroelectric Capacitor

Next, methods for manufacturing a ferroelectric film and a ferroelectric capacitor in accordance with the present embodiment are described.

(1) First, a substrate 10 is prepared. As the substrate 10, for example, silicon can be used. Next, the substrate 10 is mounted on a substrate holder, and placed in a vacuum apparatus (not shown). Within the vacuum apparatus, targets including constituting elements of a first electrode 102 and a second electrode 103 are separated at a specified distance and disposed opposite to the substrate 10. As the targets, those having compositions that are the same or similar to the compositions of the first electrode and the second electrode are preferably be used, respectively. In other words, as the targets of the first electrode 102 and the second electrode 103, for example, those containing Pt as a main composition can be used.

(2) Next, a first electrode 102 on the substrate 10. The first electrode 102 can be formed by, for example, a sputter method or a vacuum vapor deposition method. A material having Pt as a main composition may preferably be uses as the first electrode. The reason will be described later. In accordance with the present embodiment, Pt is used as the first electrode 102. It is noted that the first electrode 102 is not limited to Pt, but a known electrode material, such as, for example, Ir, IrOₓ, SrRuO₃, Nb—SrTiO₃, La—SrTiO₃, or Nb—(La,Sr)CoO₃ Can be used. Here, Nb—SrTiO₃ is SrTiO₃ doped with Nb, and La—SrTiO₃ is SrTiO₃ doped with La. Nb—(La,Sr)CoO₃ is (La,Sr)CoO₃ doped with Nb.

(3) Next, a ferroelectric film 101 is formed on the first electrode 102. In accordance with the present embodiment, cases in which the ferroelectric film 101 is Pb_{1-b}(Zr, Ti)₁₋ₐXₐO₃ (i.e., “PZTX”) are described. However, even when the ferroelectric film 101 is formed in another composition formula other than the one described above, it can be formed by a similar method.

First, by using first-third raw material liquids including at least one of Pb, Zr, Ti and X, the first-third raw material liquids are mixed in a desired mixing ratio so that the ferroelectric film 101 has a desired composition ratio. The mixed solution (precursor solution) is disposed on the first electrode 102 by an application method such as a spin coat method or a droplet ejecting method. Next, by conducting a thermal treatment such as sintering, oxides included in the precursor solution are crystallized to obtain the ferroelectric film 101.

More specifically, first, a series of steps consisting of a precursor solution coating step, a dry thermal treatment step, and a cleaning thermal treatment step are repeated a desired number of times. Next, crystallization annealing is conducted to form the ferroelectric film 101.

The raw material liquid that is the material for forming the precursor solution is formed by mixing organic metals that contain metals composing PZTX, respectively, so that each metal becomes the desire molar ratio, and dissolving or dispersing them in organic solvent such as alcohol. As the organic metals that contain metals composing PZTX respectively, metal alkoxide and organic acid salts can be used. More specifically, for example, as carboxylic acid salt or acetylacetonato complex including the PZTX constituting metals, the following can be enumerated as examples:

Lead acetate can be enumerated as an organic metal including lead (Pb), for example. Zirconium butoxide can be enumerated as an organic metal including zirconium (Zr), for example. Titanium isopropoxide can be enumerated as an organic metal including titanium (Ti), for example. Vanadium oxide acetylacetonato can be enumerated as an organic metal including vanadium (V), for example. Niobium ethoxide can be enumerated as an organic metal including niobium (Nb), for example. Tantalum ethoxide can be enumerated as an organic metal including tantalum (Ta), for example. Chrome (III) acetylacetonato can be enumerated as an organic metal including chrome (Cr), for example. Molybdenum acetate (II) can be enumerated as an organic metal including molybdenum (Mo), for example. Tungsten hexacarbonyl can be enumerated as an organic metal including tungsten (W), for example. It is noted that the organic metals including metals composing PZTX are not limited to those described above.

As the first raw material liquid, a solution in which a condensation polymer for forming PbZrO₃ perovskite crystal with Pb and Zr among the constituent metal elements of the PZTN is dissolved in a solvent such as n-buthanol in an anhydrous state can be enumerated as an example.

As the second raw material liquid, a solution in which a condensation polymer for forming PbTiO₃ perovskite crystal with Pb and Ti among the constituent metal elements of the PZTN is dissolved in a solvent such as n-buthanol in an anhydrous state can be enumerated as an example.

As the third raw material liquid, a solution in which a condensation polymer for forming PbNbO₃ perovskite crystal with Pb and Nb among the constituent metal elements of the PZTN is dissolved in a solvent such as n-buthanol in an anhydrous state can be enumerated as an example. It is noted that when X is composed of two or more types of elements, the third raw material liquid can be formed from a plurality of raw material liquids. For example, when X is composed of three kinds of elements, V, Nb and Ta, the third raw material liquid can be composed of three kinds of raw material liquids. More specifically, the third raw material liquid can be composed of a solution in which a condensation polymer for forming PbVO₃ perovskite crystal with Pb and V is dissolved in a solvent such as n-buthanol in an anhydrous state, a solution in which a condensation polymer for forming PbNbO₃ perovskite crystal with Pb and Nb is dissolved in a solvent such as n-buthanol in an anhydrous state, and a solution in which a condensation polymer for forming PbTaO₃ perovskite crystal with Pb and Ta is dissolved in a solvent such as n-buthanol in an anhydrous state.

Various additives such as a stabilizing agent and the like can be added to the raw material solution if necessary. In addition, when hydrolysis or polycondensation is to be caused in the raw material solution, acid or base can be added to the raw material solution as a catalyst with an appropriate amount of water.

In the precursor solution coating step, the mixed solution may be coated by a coating method such as spin coating. First, the mixed solution is dripped on the first electrode 102. In order to spread the dripped solution over the entire surface of the first electrode 102, spinning is conducted. The rotation speed of the spinning may be about 500 rpm in an initial stage, for example, and can be increased in succession to about 2000 rpm such that coating irregularities do not occur. In this manner, the coating can be completed.

In the dry thermal treatment step, a thermal treatment (dry treatment) is performed in the atmosphere, using a hot plate or the like, at temperatures that are about 10° C. higher than the boiling point of the solution used in the precursor solution, for example. The dry thermal treatment step may be performed at 150° C.-180° C., for example.

In the cleaning thermal treatment step, a thermal treatment is performed in the atmosphere, using a hot plate, at about 350° C.-400° C. to dissolve and remove ligands of the organic metals used in the precursor solution.

In crystallization annealing, in other words, in the sintering step for crystallization, a thermal treatment is performed in an oxygen atmosphere, at about 600° C., for example. This thermal treatment can be performed by, for example, rapid thermal anneal (RTA).

When the ferroelectric film 101 is formed, PbSiO₃ silicate may preferably be added by a ratio of 1 mol % or greater but less than 5 mol %. This can reduce the crystallization energy of the ferroelectric film 101. In other words, when, for example, PZTX is used for the ferroelectric film 101, PbSiO₃ silicate can be added, together with the dopant X, the crystallization temperature of the PZTX can be reduced. Si that is introduced here is believed to coordinate eventually to the A site of the perovskite type structure in the ferroelectric film 101. More specifically, a fourth raw material liquid can be used in addition to the first-third raw material liquids described above. As the fourth raw material liquid, a solution in which a condensation polymer for forming PbSiO₃ Crystal is dissolved in a solvent such as n-buthanol in an anhydrous state can be enumerated as an example. As an additive agent to promote crystallization, a germanate can be used. When a PbSiO3 silicate or germanate is used when the ferroelectric film 101 is formed, the ferroelectric film 101 may include Si or Si and Ge. More specifically, the ferroelectric film 101 can include Si or Si and Ge by 0.5 mol % or greater but less than 5 mol %.

The film thickness of the ferroelectric film 101 after sintering can be about 50-300 nm. In the example described above, the example of forming the ferroelectric film 101 by a liquid phase method is described. However, the ferroelectric film 101 can also be formed by using a vapor phase method, such as, a spatter method, a molecular-beam epitaxy method, a laser ablation method, or the like. To introduce X stably in the B site, a liquid phase method is the easiest manufacturing process among these methods, and preferable.

Also, when a part of Pb in the A site of the perovskite type structure in the ferroelectric film 101 is replaced with a lanthanoid element, for example, a raw material liquid may be formed by using an organic metal containing a lanthanoid element is formed, and the ferroelectric film 101 can be formed by using the raw material liquid, in a manner similar to the example described above. More specifically, for example, the following elements can be enumerated as the organic metal including lanthanoid element.

For example, lanthanum acetylacetonato dihydrate can be enumerated as an organic metal including lanthanum (La). For example, neodymium acetate (III) monohydrate can be enumerated as an organic metal including neodymium (Nd). For example, cerium acetate (III) monohydrate can be enumerated as an organic metal including cerium (Ce). For example, samarium acetate (III) tetrahydrate can be enumerated as an organic metal including samarium (Sm). For example, praseodymium acetate (III) hydrate can be enumerated as an organic metal including praseodymium (Pr). It is noted that the organic metal including a lanthanoid element is not limited to the aforementioned materials.

(4) Next, a second electrode 103 is formed on the ferroelectric film 101. The second electrode 103 can be formed by, for example, a sputter method or a vapor deposition method. A material mainly composed of Pt may preferably be used as an upper electrode. By using the material mainly composed of Pt as the second electrode 103, Pb in the ferroelectric film 101 described above can be positively vacated. This is believed to take place because the diffusion coefficient of Pb within Pt is large. By positively vacating Pb, it becomes easy to add X in the ferroelectric film 101. In other words, X can be added in a desired amount. As a result, current leakage at the ferroelectric film 101 can be prevented, and imprint, retention and fatigue characteristics of the ferroelectric film 101 can be made excellent. As described above, the same applies to the reason why the use of a material mainly composed of Pt as the first electrode 102 is preferable. In the present embodiment, Pt is used as the second electrode 103. It is noted that the second electrode 103 is not limited to Pt, but a known electrode material, such as, Ir, IrOₓ, SrRuO₃, Nb—SrTiO₃, La—SrTiO₃, Nb—(LaSr)CoO₃, or the like can be used.

Also, Pt is spontaneously oriented to (111). For this reason, the ferroelectric film 101 having a perovskite type structure formed on Pt can be readily preferentially oriented to psuedo-cubic (111), by inheriting the structure of Pt at the lower portion. When the ferroelectric film 101 that is preferentially oriented to psuedo-cubic (111) has, at the same time, a tetragonal structure, the direction of polarization axis of the ferroelectric film 101 becomes equivalent in any domain in a direction perpendicular to a surface. In other words, domains having in-plane polarization can be suppressed. For this reason, the squareness of a hysteresis loop can be drastically improved. For example, when psuedo-cubic (001) components in a tetragonal structure or psuedo-cubic (111) components in a rhombohedral structure preferentially exist, in-plane oriented polarization domains spontaneously occur. They are not desirable because polarization components thereof perpendicular to a surface contribute as inhomogeneous domains.

(5) Next, depending on the requirements, post-annealing in an oxygen atmosphere may be performed by using RTA. As a result, a good interface can be formed between the second electrode 103 and the ferroelectric film 101, and the crystallinity of the ferroelectric film 101 can be improved.

The ferroelectric film 101 and the ferroelectric capacitor 100 in accordance with the present embodiment can be manufactured through the steps described above.

### 1-3. EXPERIMENTAL EXAMPLE 1

A ferroelectric capacitor 100 was manufactured in the following manner as Experimental Example 1 based on the method of manufacturing a ferroelectric capacitor described above.

First, a substrate 10 was prepared. The substrate 10 having SiO₂ and TiOₓ deposited in layers in this order on a silicon substrate was used. Next, the substrate 10 was mounted on a substrate holder, and placed in a vacuum apparatus (not shown). Within the vacuum apparatus, targets including constituting elements of a first electrode 102 and a second electrode 103 were separated at a specified distance and disposed opposite to the substrate 10. As the targets for the first electrode 102 and the second electrode 103, Pt was used.

Next, a first electrode 102 was formed on the substrate 10. The first electrode 102 was formed by a sputter method. As the first electrode 102, Pt of a thickness of 150 nm having a (111) orientation was used.

Next, a ferroelectric film 101 was formed on the first electrode 102. First, by using first-fourth raw material liquids to be described below, the first-fourth raw material liquids were mixed in a desired mixing ratio so that the ferroelectric film 101 had a desired composition ratio. A series of steps including a step of coating the mixed solution (precursor solution), a dry thermal treatment step, and a cleaning thermal treatment step was repeated five times. Then, by conducting crystallization annealing, the ferroelectric film 101 was formed. The thickness of the finally formed ferroelectric film 101 was 200 nm.

As the first raw material liquid, a solution in which lead acetate and zirconium butoxide were mixed at a ratio of 110:100, and the mixed material is dissolved in n-buthanol in an anhydrous state was used. As the second raw material liquid, a solution in which lead acetate and titanium isopropoxide were mixed at a ratio of 110:100, and the mixed material was dissolved in n-buthanol in an anhydrous state was used. As the third raw material solution, a solution in which lead acetate and niobium ethoxide were mixed at a ratio of 110:100, and the mixed material was dissolved in n-buthanol in an anhydrous state was used. As the fourth raw material solution, a solution in which lead acetate and tetra-n-butoxysilane were mixed at a ratio of 110:100, and the mixed material was dissolved in n-buthanol in an anhydrous state was used. These first raw material liquid, second raw material liquid, third raw material liquid and fourth raw material liquid were mixed at a ratio of 20:60:20:1, to obtain the precursor solution.

In the step of coating the precursor solution, the mixed solution was coated by spin coating. First, the mixed solution was dripped on the first electrode 102. In order to spread the dripped solution over the entire surface of the first electrode 102, spinning was conducted. The spinning was conducted for 30 seconds at 2000 rpm-5000 rpm. In this manner, the coating was completed.

In the dry thermal treatment step, a thermal treatment (dry treatment) was performed in the atmosphere, using a hot plate, at 150° C. for 2 min. In the cleaning thermal treatment step, a thermal treatment was performed in the atmosphere, using a hot plate, at 300° C. for 4 min. In the sintering step for crystallization, a thermal treatment was performed in an oxygen atmosphere, at 600° C.-700° C. for 5 min. This thermal treatment was performed by rapid thermal anneal (RTA). The film thickness of the ferroelectric film 101 after sintering was 200 nm.

Next, a second electrode 103 was formed on the ferroelectric film 101. The second electrode 103 was formed by a sputter method. As the upper electrode, Pt that was 150 nm thick was used. Next, post annealing was performed in an oxygen atmosphere by RTA. The post annealing was performed at 700° C. for 15 min.

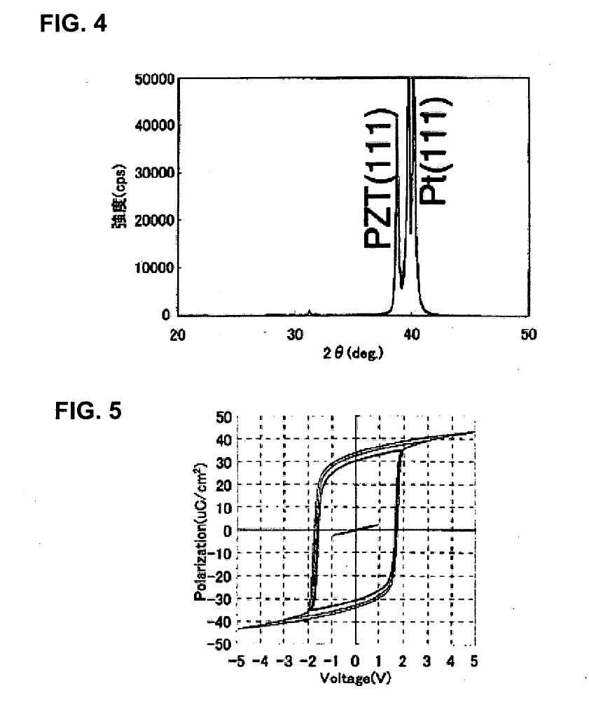

The ferroelectric capacitor 100 obtained in this manner, in particular, its ferroelectric film 101 was analyzed by an X ray diffraction (XRD) method. The result thereof is shown in FIG. 4. From the result, it was confirmed that the ferroelectric film 101 was a single layer having a perovskite type structure and was preferentially oriented to psuedo-cubic (111). Also, its Raman scattering was examined, and it was confirmed that the system had a tetragonal structure.

Also, as a result of evaluation of electrical characteristics of the ferroelectric capacitor 100, P-E hysteresis characteristics having good squareness shown in FIG. 5 were obtained. When a polarization Pr was about 35 μC/cm², the ferroelectric characteristic with a coercive filed Ec that was 80 kV/cm (because polarization is zero when a voltage is ±1.6 V, Ec=1.6 V/200 nm=80 kV/cm) was confirmed. It deserves special mention that, although having very good squareness and a large coercive filed of about 80 kV/cm, the ferroelectric hysteresis is almost saturated with an impressed electric field of 100 kV/cm.

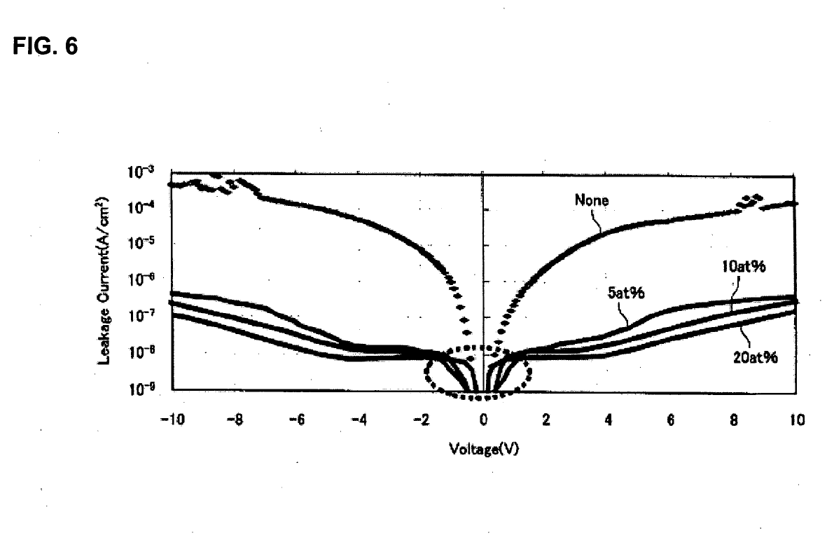

Next, FIG. 6 shows leakage current characteristics. The doping amount of Nb in the experimental example is 20 at % in the composition ratio to the entire transition metal atoms. FIG. 6 shows comparison examples in which the doping amounts of Nb are 0 at %, 5 at % and 10 at %, respectively. When the doping amount of Nb is 0 at %, in other words, in the case of conventional PZT, the leakage characteristic is very poor. When the doping amount of Nb is 5 at %, the leakage characteristic shows some improvements, but still includes many ohmic current regions as indicated in a circle with a broken line in FIG. 6, which indicates that the improvements are not sufficient. When the doping amount of Nb is 10 at % and 20 at %, the ohmic current regions in the leakage characteristic are substantially improved.

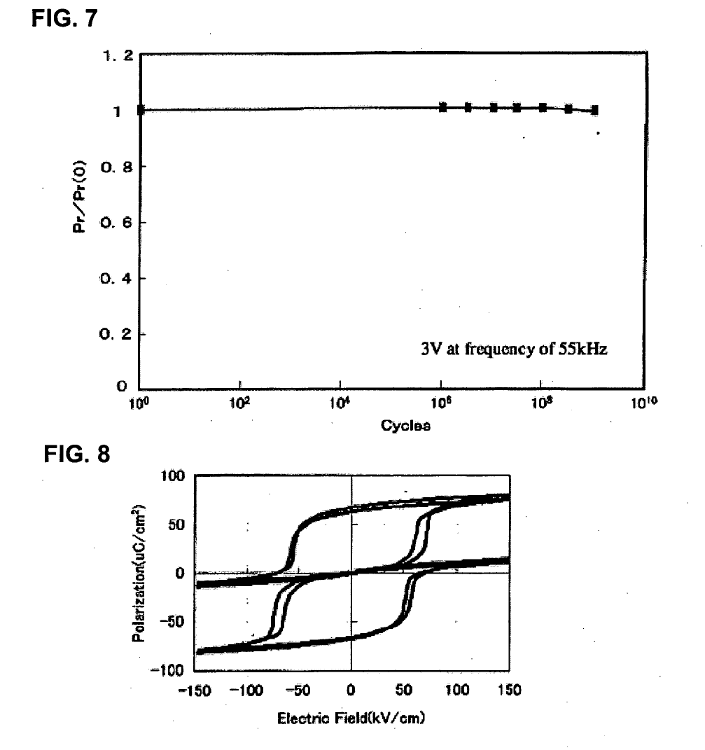

Next, FIG. 7 shows fatigue characteristics. It is known that, when a platinum electrode is used, PZT generally deteriorates until its polarization is reduced to half at 10⁹ Cycle load tests. In contrast, in the case of the ferroelectric film 101 of the present experimental example, the polarization scarcely deteriorates.

Next, evaluation results of the imprint characteristics and data retention characteristics are described, and their measurement methods are performed according to: J. Lee, R. Ramesh, V. Karamidas, W. Warren, G. Pike and J. Evans., Appl. Phys. Lett., 66, 1337 (1995); and M. Bratkovsky and A. P. Levanyuk. Phys. Rev. Lett., 84, 3177 (2000) as follows.

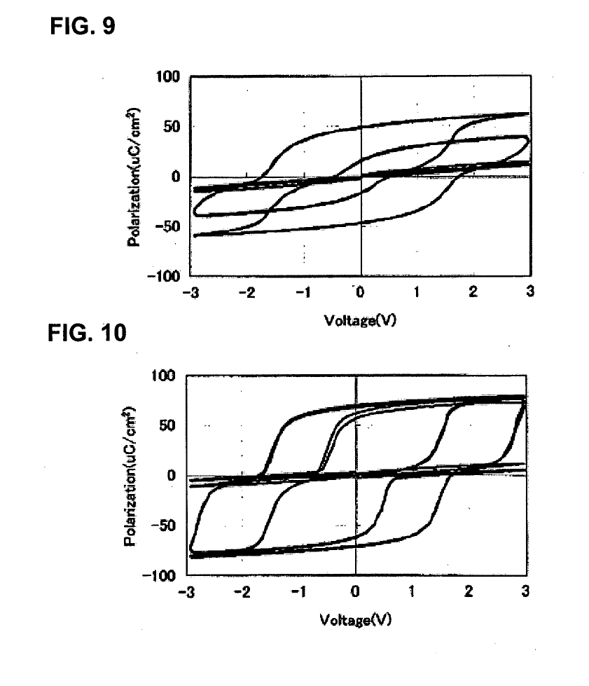

Next, evaluation tests on the static imprint characteristics were conducted under the constant temperature environment at 150° C., and the results shown in FIG. 8-FIG. 10 were obtained. FIG. 8 shows the result on the ferroelectric film 101 of the present experimental example. As comparison examples, FIG. 9 shows the result on a PZT (Zr/Ti=20/80) film, and FIG. 10 shows the result on a PZT (Zr/Ti=30/70) film. In the case of the PZT, the polarization at the time of reading is lost by 40%, but in the case of the ferroelectric film 101 of the present experimental example, the polarization at reading scarcely changes. In other words, as shown in FIG. 8-FIG. 10, it was confirmed that the ferroelectric film 101 of the present experimental example had good imprint characteristics.

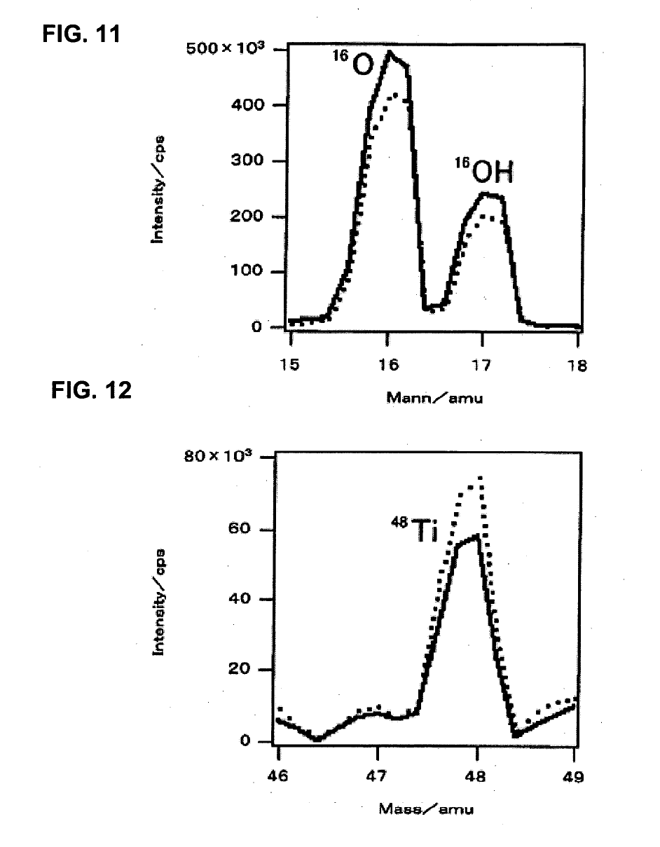

Next, in order to confirm if the high reliability of the ferroelectric film 101 of the present experimental example can be obtained because oxygen vacancy is prevented as described above, a variety of analysis was conducted. First, the amount of oxygen vacancy was examined by using secondary ion mass spectrometry (SIMS), and the results shown in FIG. 11 and FIG. 12 were obtained. A solid line in each of the figures indicates the case of the ferroelectric film 101 of the present experimental example, and a broken line indicates the case of PZT. As shown in FIG. 11, it was confirmed that the ferroelectric film 101 of the present experimental example had an oxygen concentration that is about 10% higher than that of PZT, and this is believed to prove the oxygen vacancy suppressing effect caused by the addition of Nb. Also, as shown in FIG. 12, the Ti concentration is about 10% lower, compared to PZT, and it was confirmed that the Ti content is lower by the amount it is replaced with Nb.

Next, because SIMS does not provide high measuring sensitivity for Nb, Nb concentration was measured by using X-ray photoelectron spectroscopy (XPS). The result is shown in Table 1.

TABLE 1

| Unit | Pb-4f | Zr-3d | Ti-2p | Nb-3d | 0-1s | Si-2p | Total |
|---|---|---|---|---|---|---|---|
| atomic % | 24.4 | 5.7 | 15.3 | 5.7 | 48.8 | 0.1 | 100 |

According to the results, it was confirmed that the ferroelectric film 101 of the present experimental example is expressed by Pb_{1-b}(Zr₁₋ₚTiₚ)₁₋ₐNbₐO₃, where a is about 0.21, b is about 0.086, and p is about 0.73. These values are within the preferred numerical value range of a, b and p described above.

### 1-4. EXPERIMENTAL EXAMPLE 2

A ferroelectric capacitor 100 was manufactured in the following manner as Experimental Example 2 based on the method of manufacturing a ferroelectric capacitor described above.

First, a substrate 10 composed of a silicon substrate was prepared. Next, the substrate 10 was mounted on a substrate holder, and placed in a vacuum apparatus (not shown). Within the vacuum apparatus, targets including constituting elements of a first electrode 102 and a second electrode 103 were separated at a specified distance and disposed opposite to the substrate 10. As the targets for the first electrode 102 and the second electrode 103, Pt was used.

Next, a first electrode 102 was formed on the substrate 10. The first electrode 102 was formed by a sputter method. As the first electrode 102, Pt that was 150 nm thick and has a (111) orientation was used.

Next, a ferroelectric film 101 was formed on the first electrode 102. First, by using first-fourth raw material liquids to be described below, the first-fourth raw material liquids were mixed in a desired mixing ratio so that the ferroelectric film 101 had a desired composition ratio. A series of steps including a step of coating the mixed solution (precursor solution), a dry thermal treatment step, and a cleaning thermal treatment step was repeated five times. Then, by conducting crystallization annealing, the ferroelectric film 101 was formed. The thickness of the finally formed ferroelectric film 101 was 200 nm.

As the first raw material liquid, a solution in which lead acetate and zirconium butoxide were mixed at a ratio of 110:100, and the mixed material is dissolved in n-buthanol in an anhydrous state was used. As the second raw material liquid, a solution in which lead acetate and titanium isopropoxide were mixed at a ratio of 110:100, and the mixed material was dissolved in n-buthanol in an anhydrous state was used. As the third raw material solution, a solution in which lead acetate and niobium ethoxide were mixed at a ratio of 110:100, and the mixed material was dissolved in n-buthanol in an anhydrous state was used. As the fourth raw material solution, a solution in which lead acetate and tetra-n-butoxysilane were mixed at a ratio of 110:100, and the mixed material was dissolved in n-buthanol in an anhydrous state was used. These first raw material liquid, second raw material liquid, third raw material liquid and fourth raw material liquid were mixed at a ratio of 20:60: N:1, to obtain the precursor solution. In the experimental examples, N (the doping amount of Nb) was changed from 0, 5, 10, 20, 30, 40 To 45, and ferroelectric characteristics were compared. It is noted that methyl succinate was added to the precursor solution so that its pH became 6.

In the step of coating the precursor solution, the mixed solution was coated by spin coating. First, the mixed solution was dripped on the first electrode 102. In order to spread the dripped solution over the entire surface of the first electrode 102, spinning was conducted. The spinning was conducted at 500 rpm for 10 seconds, and then at 50 rpm for 10 seconds. In this manner, the coating was completed.

In the dry thermal treatment step, a thermal treatment (dry treatment) was performed in the atmosphere, using a hot plate, at 150° C.-180° C. for 2 min. In the cleaning thermal treatment step, a thermal treatment was performed in the atmosphere, using a hot plate, at 300° C.-350° C. for 5 min. In the sintering step for crystallization, a thermal treatment was performed in an oxygen atmosphere, at 650° C. for 10 min. This thermal treatment was performed by rapid thermal anneal (RTA). The film thickness of the ferroelectric film 101 after sintering was 200 nm.

Next, a second electrode 103 was formed on the ferroelectric film 101. The second electrode 103 was formed by a sputter method. As the upper electrode, Pt that was 150 nm thick was used. Next, post annealing was performed in an oxygen atmosphere by RTA. The post annealing was performed at 700° C. for 10 min.

The ferroelectric film 101 obtained in this manner was analyzed by an X-ray diffraction (XRD) method. It was confirmed that the ferroelectric film 101 was a single layer having a perovskite type structure and was preferentially oriented to psuedo-cubic (111). Also, its Raman scattering was examined, and it was confirmed that the system had a tetragonal structure.

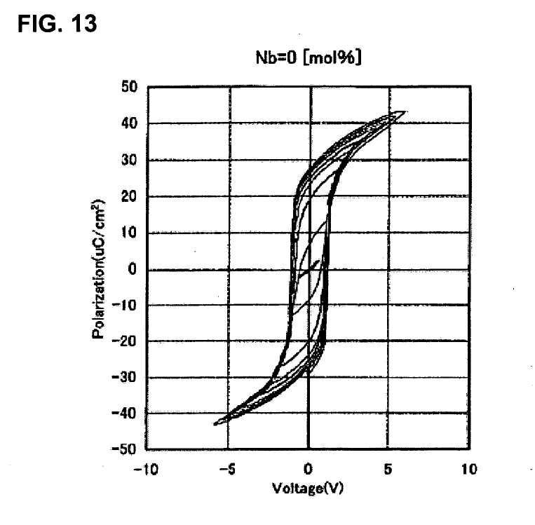

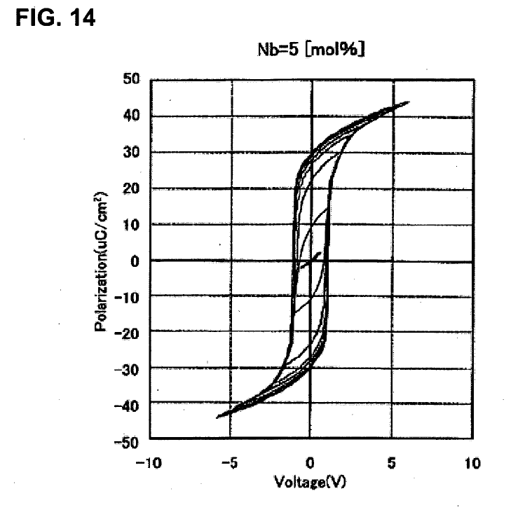

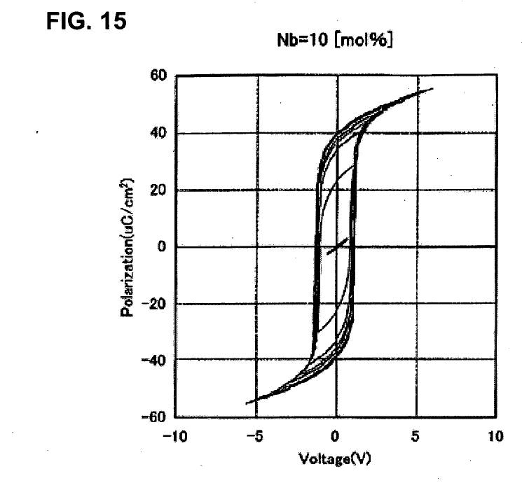

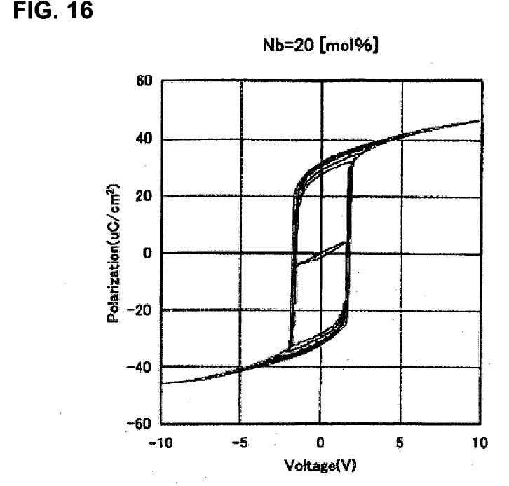

Hysteresis characteristics of the ferroelectric film 101 of the present experimental example thus obtained are shown in FIG. 13-FIG. 18. As shown in FIG. 13, when the doping amount of Nb was zero, a leaky hysteresis was obtained, but as shown in FIG. 14, when the doping amount of Nb was 5 at %, good hysteresis characteristics with high insulation were obtained. Also, as shown in FIG. 15, the hysteresis characteristics showed almost no changes until the doping amount of Nb was 10 at %. Also, as shown in FIG. 16, when the doping amount of Nb was 20 at %, hysteresis characteristics having very good squareness were obtained.

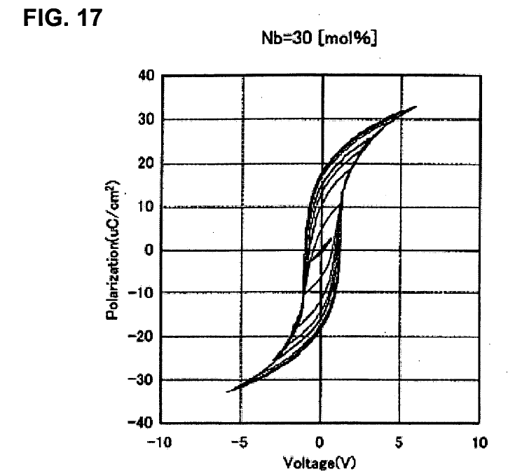

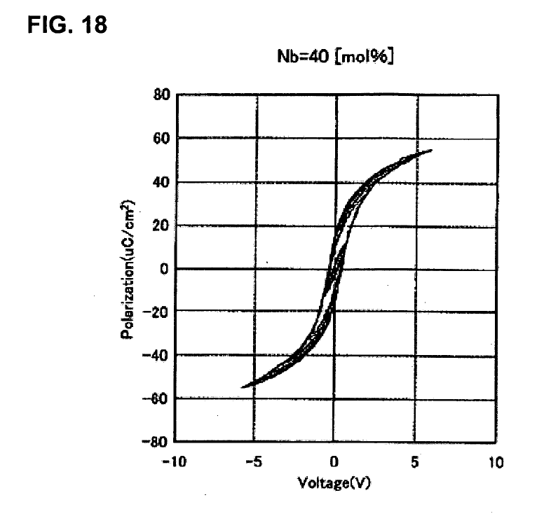

However, as shown in FIG. 17 and FIG. 18, it was confirmed that, when the doping amount of Nb exceeds 20 at %, the hysteresis characteristics greatly changed, and started deterioration. Also, when Nb was added by 45 at %, a hysteresis did not open, and no ferroelectric characteristics were confirmed (illustration omitted).

Next, the composition ratio of the ferroelectric film 101 was examined by XPS. In particular, attention was paid to the composition ratio s of Pb, and the sum q of composition ratios of the transition metal atoms, Zr, Ti and Nb. If Pb at the A site has no vacancy, s should be equal to q (s=q). However, if Pb is vacated, s<q is established, and (q−s)/q corresponds to the amount of vacancy of Pb. This is based on two considerations, i.e., the chemical equation and the fact that B site transition metal atoms are difficult to be vacated compared to Pb. Table 2 shows the amount of Pb vacancy with respect to the doping amount T of Nb (at %). It is noted that the doping amount of Nb is T (at %) at the B site, and the amount of Pb vacancy is U (at %) at the A site.

TABLE 2

| T (at %) | U (at %) |
|---|---|
| 5 | 2.4 |
| 10 | 5.0 |
| 20 | 10.1 |
| 30 | 14.8 |

(Error ±0.5 at %)

According to the result, it was confirmed that the amount b of Pb vacancy with respect to the doping amount a of Nb is indicated by b≅a/2, and its range was 0.025≦b≦0.15.

### 1-5. EXPERIMENTAL EXAMPLE 3

Ferroelectric capacitors 100 were manufactured by a method similar to Experimental Example 1 described above while the composition ratio of Ti and Zr was changed. It is noted that the mixing ratio of a first raw material liquid and a second raw material liquid was (100−R): R. Also, the mixing ration of a mixed solution of the first raw material liquid and the second raw material liquid, a third raw material liquid and a fourth raw material liquid was 80:20:1.

In the present experimental example, samples with R being 100, 90, 80, 70, 60, 50, 40, 30, 20 and 10 were manufactured. Also, remanence moment was measured after fatigue tests were conducted 1×10⁻⁹ times. Table 3 shows remanence moments P of the respective samples. It is noted that P indicates a relative value when the remanence moment of the ferroelectric capacitor 100 when R is 60 (which is 30 μC/cm²) is 1.

TABLE 3

| R | P |
|---|---|
| 100 | 0.5 |
| 90 | 0.6 |
| 80 | 0.8 |
| 70 | 1.0 |
| 60 | 1.0 |
| 50 | 0.9 |
| 40 | 0.6 |
| 30 | 0.4 |
| 20 | 0.05 |
| 10 | 0.00 |

As indicated in Table 3, as to the samples with R being 20 and 10, their remanence moment is small, which is not desirable. Also, as to the samples with R being 90 and 100, their leakage current is high at 2×10⁻⁴ (A/cm²) at 3 V, which is not desirable. In other words, it was confirmed that p in the composition formula Pb(Zr₁₋ₚTiₚ)O₃ of PZT which is a base material of PZTX may preferably be in the range of 0.3≦p≦1.0, and more preferably be in the range of 0.5≦p≦0.8.

### 1-6. EXPERIMENTAL EXAMPLE 4

Ferroelectric capacitors 100 with La being added were manufactured by a method similar to Experimental Example 1 described above. In addition to the first-fourth raw material liquids in Experimental Example 1, lanthanum acetylacetonato dihydrate was used as a fifth raw material liquid. The mixing ratio of the first raw material liquid, the second raw material liquid, the third raw material liquid, the fourth raw material liquid and the fifth raw material liquid was 20:60:20:1: L, wherein L was 1, 3, 5 and 7.

The composition ratio of Pb and La in the ferroelectric film 101, (100−R):R, and the vacancy ratio Q at the A site were examined by XPS. Q was estimated by examining as to how much smaller the sum of the composition ratios of Pb and La is from 100 when the sum of composition ratios of B site transition metal atoms is assumed to be 100. Also, remanence moment P was measured after fatigue tests were conducted 1×10⁻⁹ Times. The results are shown in Table 4.

TABLE 4

| L | R | Q (%) | P (μC/cm²) |
|---|---|---|---|
| 1 | 0.9 | 10 | 25 |
| 3 | 3.1 | 11 | 22 |
| 5 | 4.9 | 14 | 11 |
| 7 | 7.4 | 16 | 3 |

All of the samples show low values of leakage current of 1×10⁻⁶ (A/cm²) at 3 V, which is desirable. When L is 7, the remanence P is small, which is not desirable. Accordingly, the doping amount is desirous to be 5 or less. In this case, the vacancy ratio Q in the A low 15%.

### 1-7. EXPERIMENTAL EXAMPLE 5

Ferroelectric capacitors 100 with Mo being added were manufactured by a method similar to Experimental Example 1 described above. In addition to the first-fourth raw material liquids in Experimental Example 1, a solution in which lead acetate and molybdenum acetate (II) are mixed, and the mixed material was dissolved in n-buthanol in an anhydrous state was used as a fifth raw material liquid. The mixing ratio of the first raw material liquid, the second raw material liquid, the third raw material liquid, the fourth raw material liquid and the fifth raw material liquid was 20:60:15:1:5.

The composition ratio of the ferroelectric film 101 was examined by XPS. Pb:Zr:Ti:Nb:Mo was 88:20:60:15:5. Accordingly, the amount of Pb vacancy b at the A site is expressed by 100−88=12. It was confirmed that the amount of vacancy b was generally equal to the sum (i.e., 12.5) of a half of the doping amount (a−e) of Nb of 5+ ion (i.e., 7.5 which is a half of 15) and the doping amount e of Mo of 6+ ion (i.e., 5). Accordingly, it was confirmed from the present experimental example that, when X in the ferroelectric film 101 that is composed of PZTX includes X1 of 5+ ion and X2 of 6+ ion, the amount of vacancy b at the A site is generally equal to the sum of a half of the doping amount of X1 which is (a−e)/2, and the doping amount e of X2.

The samples of the present experimental example show low values of leakage current of 2×10⁻⁶ (A/cm²) at 3 V, which is desirable. Also, remanence moment, after fatigue tests were conducted 1×10⁻⁹ Times, was 26 (μC/cm²), which is desirable.

### 1-8. REFERENCE EXAMPLE

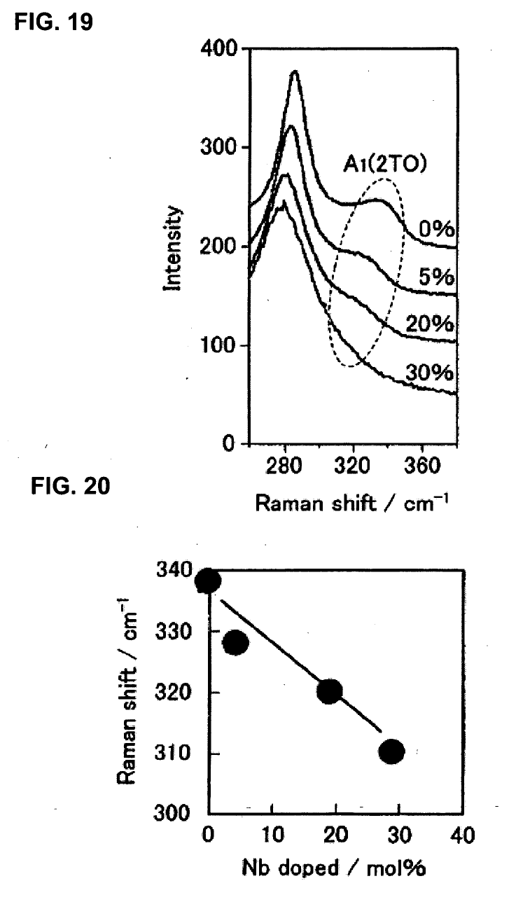

PTN (PbTi₁₋ₓNbₓO₃: X=0−0.3) films in which the doping amount of Nb was changed were formed by a film forming method similar to Experimental Example 2 described above as reference examples, and they were analyzed by Raman spectroscopy. FIG. 19 shows Raman optical spectra. The Raman optical spectra indicate that, in all of the samples with X=0−0.3, the ferroelectric films have a tetragonal structure.

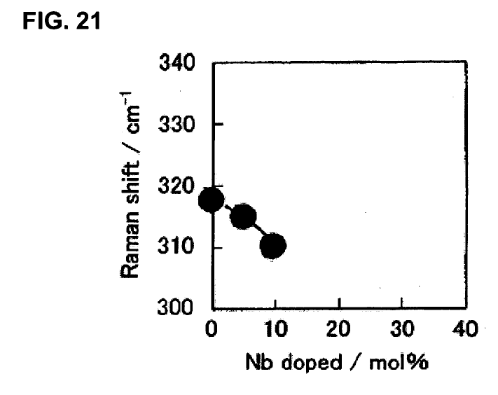

Peaks indicative of vibration mode that originates in B site ions called A₁ (2TO) (indicated by a circle with broken line in FIG. 19) shift toward the lower wave number side with an increase in the doping amount of Nb, as shown in FIG. 20. This indicates that Nb is substituted for at the B site. Further, in FIG. 21 that indicates the case of PZTN (Pb Zr_{Y} Ti_{1-Y-X} Nb_{X}O₃:X=0−0.1), it can be confirmed that Nb is substituted for at the B site.

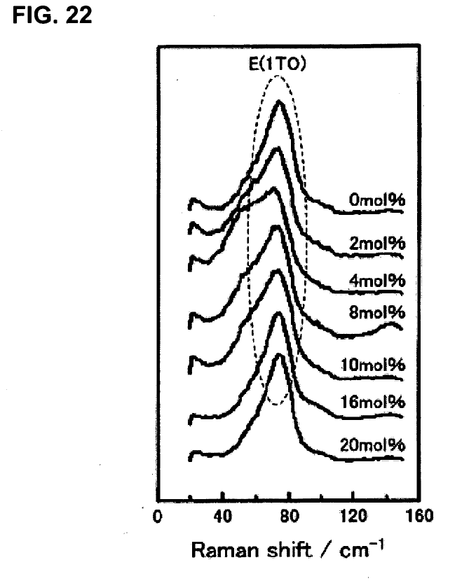

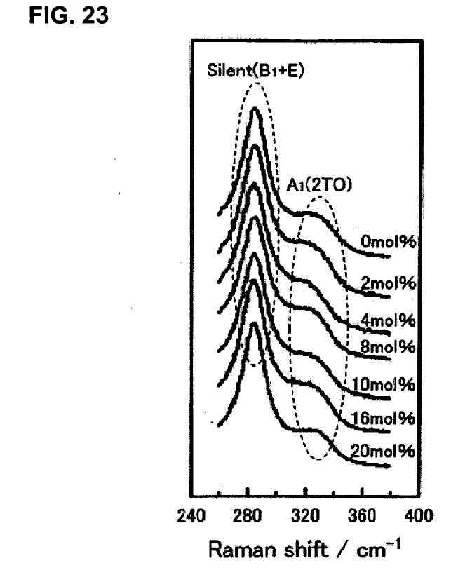

Next, PT (PbTiO₃) films in which the doping amount of Si was changed were formed by a film forming method similar to Experimental Example 1 described above, and they were analyzed by Raman spectroscopy. FIG. 22 and FIG. 23 show Raman optical spectra. Si was added as PbSiO₃ by 20 mol % or less for 1 mol of PbTiO₃. It is noted that the doping amount of Si here indicates the doping amount thereof as in PbSiO₃.

As shown in FIG. 22 and FIG. 23, as the doping amount of Si increases, a shift was observed in peaks indicative of vibration mode of A site ions called E (1TO), and no change was observed in vibration mode of B site ions called A₁ (2TO). In other words, it is confirmed that Si changes to Si²⁺, and is partially substituted for Pb at the A site. Therefore, it can be guessed that, in a ferroelectric film (for example, PZTX or the like) having a perovskite type structure expressed by ABO₃ such as PT, Si changes to Si²⁺, and is partially substituted for atoms at the A site.

1-9. Actions and Effects

By the ferroelectric capacitor 100 in accordance with the present embodiment, hysteresis characteristics having good squareness and excellent fatigue characteristics can be obtained. Also, by the ferroelectric film 101 in accordance with the present embodiment, excellent leakage characteristics and imprint characteristics can be obtained. Accordingly, the ferroelectric film 101 in accordance with the present embodiment can be used for memories regardless of the memory type or structure.

Influences on the hysteresis characteristics of the ferroelectric capacitor 100 that may be caused by the use of the ferroelectric film 101 in accordance with the present embodiment are considered below.

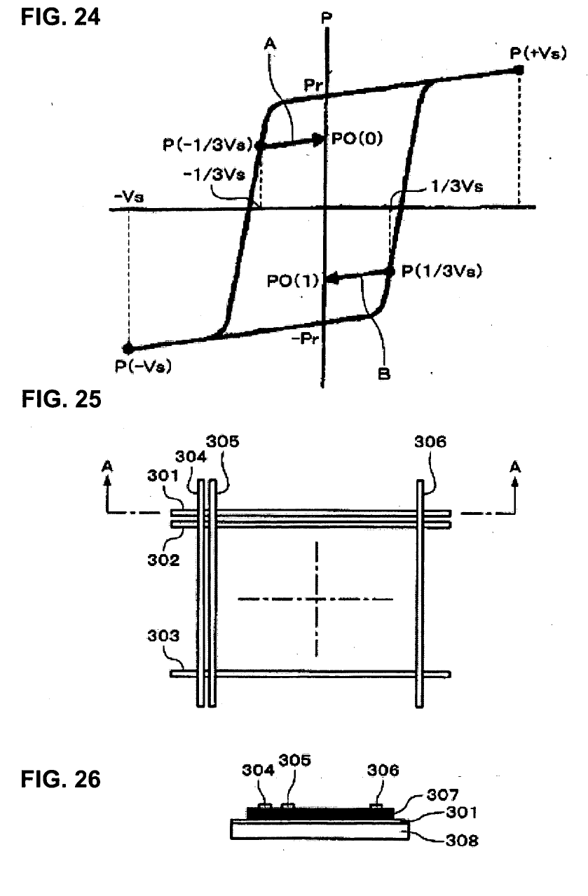

FIG. 24 is a view schematically showing a P (polarization)−V (voltage) hysteresis curve of the ferroelectric capacitor 100. First, the polarization is P (+Vs) upon application of a voltage of +Vs, and then the polarization becomes Pr upon application of a voltage of 0. Further, the polarization becomes P (−⅓ Vs) upon application of a voltage of −⅓ Vs. Then, the polarization becomes P (−Vs) upon application of a voltage of −Vs, and the polarization becomes −Pr when the voltage is returned to 0. Further, the polarization becomes P (+⅓ Vs) upon application of a voltage of +⅓ Vs, and the polarization returns again to P (+Vs) when the voltage is returned to +Vs.

Also, the ferroelectric capacitor 100 has the following characteristics in the hysteresis characteristics. First, after applying a voltage of Vs to cause the polarization P (+Vs), a voltage of −⅓ Vs is applied and the applied voltage is then changed to 0. In this case, the hysteresis loop follows a locus indicated by an arrow A shown in FIG. 24, and the polarization has a stable value of P0 (0). After applying a voltage of −Vs to cause the polarization P (−Vs), a voltage of +⅓ Vs is applied and the applied voltage is then changed to 0. In this case, the hysteresis loop follows a locus indicated by an arrow shown in FIG. 24 and the polarization has a stable Value of P0 (1). If the difference between the polarization P0 (0) and the polarization P0 (1) is sufficiently secured, a simple matrix type ferroelectric memory device can be operated by using the drive method disclosed in Japanese Laid-open Patent Application No. 9-116107 or the like.

According to the ferroelectric capacitor 100 in accordance with the present embodiment, a decrease in crystallization temperature, an increase in squareness of the hysteresis, and an increase in Pr can be achieved. The increase in squareness of the hysteresis of the ferroelectric capacitor 100 has significant effects on stability against disturbance, which is important for driving the simple matrix type ferroelectric memory device. In the simple matrix type ferroelectric memory device, since a voltage of ±⅓ Vs is applied to the cells in which neither writing nor reading is performed, the polarization must not be changed at this voltage, in other words, disturbance characteristics need to be stable. In practice, the polarization of ordinary PZT is decreased by about 80% when a ⅓ Vs pulse is applied 10⁸ times in the direction in which the polarization is reversed from a stable state. However, it was confirmed that it was 10% or less according to the ferroelectric capacitor 100 of the present embodiment. Accordingly, by applying the ferroelectric capacitor 100 of the present embodiment to a ferroelectric memory device, a simple matrix type ferroelectric memory device can be put to practical use.

### 2. Second Embodiment

FIG. 25 and FIG. 26 are views showing a configuration of the simple matrix type ferroelectric memory device of the present embodiment. FIG. 25 is a plan view of the ferroelectric memory device, and FIG. 26 is a cross-sectional view taken along a line A-A shown in FIG. 25. The ferroelectric memory device includes, as shown in FIG. 25 and FIG. 26, a predetermined number of word lines 301-303 arranged and formed on a substrate 308, and a predetermined number of bit lines 304-306 arranged thereon. A ferroelectric film 307 described above in the present embodiment is interposed between the word lines 301-303 and the bit lines 304-306, wherein ferroelectric capacitors are formed in intersecting regions of the word lines 301-303 and the bit lines 304-306.

In the ferroelectric memory device 300 in which memory cells are arranged in a simple matrix, writing in and reading from the ferroelectric capacitors formed in the intersecting regions of the word lines 301-303 and the bit lines 304-306 are performed by a peripheral driver circuit, reading amplifier circuit, and the like (not shown) (which are hereinafter called “peripheral circuit”). The peripheral circuit may be formed by MOS transistors on a substrate different from that of the memory cell array and connected with the word lines 301-303 and the bit lines 304-306, or by using a single crystal silicon on the substrate 308, the peripheral circuit may be integrated on the same substrate with the memory cell array.

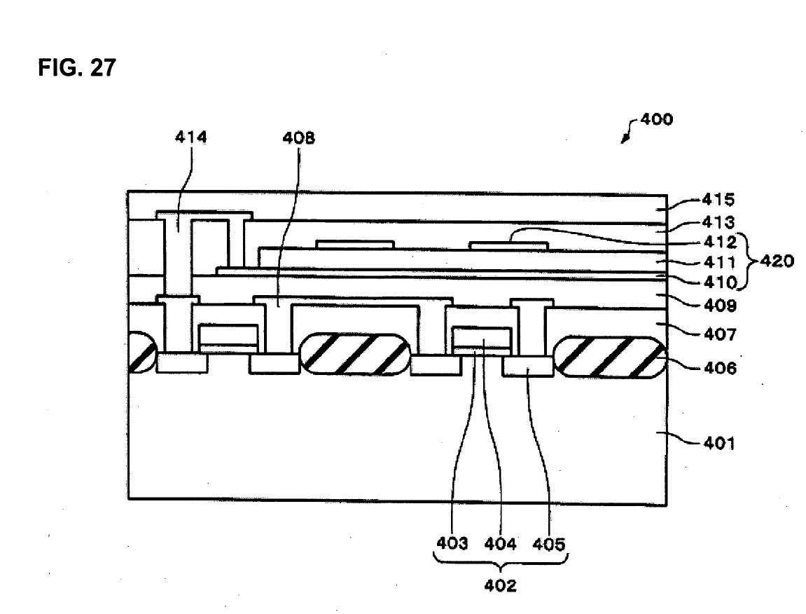

FIG. 27 is a cross-sectional view showing an example of a ferroelectric memory device 400 in accordance with the present embodiment in which a memory cell array is integrated with a peripheral circuit on the same substrate.

Referring to FIG. 27, MOS transistors 402 are formed on a single crystal silicon substrate 401, and the region where the transistors are formed defines a peripheral circuit section. The MOS transistor 402 is composed of a single crystal silicon substrate 401, a source/drain region 405, a gate dielectric film 403, and a gate electrode 404. Also, the ferroelectric memory device 400 has an element isolation oxide film 406, a first interlayer dielectric film 407, a first wiring layer 408, and a second interlayer dielectric film 409.

Also, the ferroelectric memory device 400 has a memory cell array composed of ferroelectric capacitors 420, and each of the ferroelectric capacitors 420 is composed of a lower electrode (first electrode or second electrode) 410 that defines a word line or a bit line, a ferroelectric film 411 including ferroelectric phase and paraelectric phase, and an upper electrode (second electrode or first electrode) 412 that is formed on the ferroelectric film 411 and defines a bit line or a word line.

Furthermore, the ferroelectric memory device 400 has a third interlayer dielectric film 413 over the ferroelectric capacitor 420, and a second wiring layer 414 connects the memory cell array and the peripheral circuit section. It is noted that, in the ferroelectric memory device 400, a protection film 415 is formed over the third interlayer dielectric film 413 and the second wiring layer 414.

According to the ferroelectric memory device 400 having the structure described above, the memory cell array and the peripheral circuit section can be integrated on the same substrate. It is noted that, although the ferroelectric memory device 400 shown in FIG. 27 has a structure in which the memory cell array is formed over the peripheral circuit section, the memory cell array may not be disposed over the peripheral circuit section, but may be structured to be in contact with the peripheral circuit section in a plane.

Because the ferroelectric capacitor 420 used in the present embodiment is formed from the ferroelectric film in accordance with the present embodiment, its hysteresis has excellent squareness, and its disturbance characteristics is stable. Moreover, damage to the peripheral circuit and other elements is reduced due to the lowered process temperature, and process damage (reduction by hydrogen, in particular) is small, such that the ferroelectric capacitor 420 can suppress deterioration of the hysteresis that may be caused by such damages. Therefore, the simple matrix type ferroelectric memory device 300 can be put in practical use by using the ferroelectric capacitor 420.

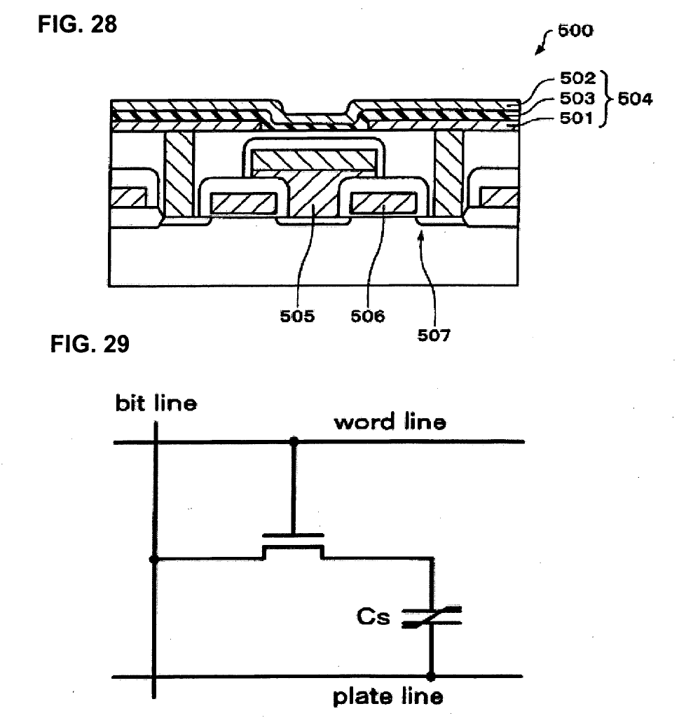

FIG. 28 shows a structural drawing of a 1T1C type ferroelectric memory device 500 as a modified example. FIG. 29 is an equivalent circuit diagram of the ferroelectric memory device 500.

As shown in FIG. 28, the ferroelectric memory device 500 is a memory element having a structure similar to that of a DRAM, which is composed of a capacitor 504 (1C) comprising a lower electrode 501, an upper electrode 502 that is connected to a plate line, and a ferroelectric film 503 in accordance with the embodiment described above, and a switching transistor element 507 (1T), having source/drain electrodes, one of them being connected to a data line 505, and a gate electrode 506 that is connected to a word line. The 1T1C type memory can perform writing and reading at high-speeds at 100 ns or less, and because written data is nonvolatile, it is promising in the replacement of SRAM.

Details of the exemplary embodiments of the present invention are described above. However, those skilled in the art would readily understand that many modifications can be made without substantively departing from the novelty and effects of the present invention. Accordingly, all of these modified examples would be included in the range of the present invention.

1. A ferroelectric film expressed by a general formula of A_{1-b}B₁₋ₐXₐO₃, wherein:
A includes Pb;
B is composed of at least one of Zr and Ti;
X is composed of at least one of V, Nb, Ta, Cr, Mo and W;
a is in a range of 0.05≦a≦0.3; and
b is in a range of 0.025≦b≦0.15.

2. A ferroelectric film expressed by a general formula of (A_{1-d}Z_{d})_{1-b}B₁₋ₐXₐO₃, wherein:
A is composed of at least Pb;
Z is composed of at least one of elements having a valence higher than A;
B is composed of at least one of Zr and Ti;
X is composed of at least one of V, Nb, Ta, Cr, Mo and W;
a is in a range of 0.05≦a≦0.3;
b is in a range of 0.025≦b≦0.15; and
d is in a range of 0≦d≦0.05.

3. A ferroelectric film according to claim 2, wherein Z is composed of at least one of La, Ce, Pr, Nd and Sm.

4. A ferroelectric film according to claim 2, wherein:
X is composed of at least one of V, Bn and Ta; and
a vacancy amount b of A is about a half of a doping amount a of X.

5. A ferroelectric film according to claim 2, wherein:
X is composed of at least one of Cr, Mo and W; and
a vacancy amount b of A is about the same as a doping amount a of X.

6. A ferroelectric film according to claim 2, wherein:
X includes X1 and X2;
a composition ratio of X1 and X2 is expressed by (a−e): e;
X1 is composed of at least one of V, Nb and Ta;
X2 is composed of at least one of Cr, Mo and W; and
a vacancy amount b of A is approximately the sum of a half of a doping amount of X1 (a−e)/2 and a doping amount e of X2.

7. A ferroelectric film according to claim 2, wherein X exists in a B site having a perovskite type structure.

8. A ferroelectric film according to claim 2, wherein a composition ratio of Zr and Ti in B is expressed by (1−p): p, wherein p is in a range of 0.3≦p≦1.0.

9. A ferroelectric film according to claim 2, including at least one of:
Si; and
Si and Ge.

10. A ferroelectric film according to claim 2, having a tetragonal structure, and being oriented to psuedo-cubic (111).

11. A ferroelectric capacitor having the ferroelectric film according to claim 2.

12. A ferroelectric memory having the ferroelectric film according to claim 2.

13. A ferroelectric film according to claim 1, wherein:
X is composed of at least one of V, Bn and Ta; and
a vacancy amount b of A is about a half of a doping amount a of X.

14. A ferroelectric film according to claim 1, wherein:
X is composed of at least one of Cr, Mo and W; and
a vacancy amount b of A is about the same as a doping amount a of X.

15. A ferroelectric film according to claim 1, wherein:
X includes X1 and X2;
a composition ratio of X1 and X2 is expressed by (a−e): e;
X1 is composed of at least one of V, Nb and Ta;
X2 is composed of at least one of Cr, Mo and W; and
a vacancy amount b of A is approximately the sum of a half of a doping amount of X1 (a−e)/2 and a doping amount e of X2.

16. A ferroelectric film according to claim 1, wherein X exists in a B site having a perovskite type structure.

17. A ferroelectric film according to claim 1, wherein a composition ratio of Zr and Ti in B is expressed by (1−p): p, wherein p is in a range of 0.3≦p≦1.0.

18. A ferroelectric film according to claim 1, including at least one of
Si; and
Si and Ge.

19. A ferroelectric film according to claim 1, having a tetragonal structure, and being oriented to psuedo-cubic (111).

20. A ferroelectric capacitor having the ferroelectric film according to claim 1.

21. A ferroelectric memory having the ferroelectric film according to claim 1.
